(19) United States
(12) Patent Application Publication
(10) Pub. No.: US 2026/0150516 A1
(43) Pub. Date: May 28, 2026

(54) DISPLAY PANEL AND MANUFACTURING METHOD THEREOFFOR, AND DISPLAY DEVICE

(71) Applicants: Mianyang HKC Optoelectronics Technology Co.,Ltd., MIANYANG (CN); HKC CORPORATION LIMITED, SHENZHEN (CN)

(72) Inventors: Yao LI, MIANYANG (CN); Haijiang YUAN, MIANYANG (CN)

(73) Assignees: Mianyang HKC Optoelectronics Technology Co.,Ltd., MIANYANG (CN); HKC CORPORATION LIMITED, SHENZHEN (CN)

(21) Appl. No.: 19/383,591

(22) Filed: Nov. 8, 2025

(30) Foreign Application Priority Data
Nov. 28, 2024 (CN) 202411730518.0

(51) Int. Cl. H10K 59/122

(52) U.S. Cl. CPC H10K 59/122

(57) ABSTRACT

A display panel and a manufacturing method therefor, and a display device are disclosed. The display panel includes a substrate, a plurality of sub-pixels, a pixel definition layer, and an overhang structure. Each sub-pixel includes a first electrode, a light-emitting layer, and a second electrode. The overhang structure is disposed on the pixel definition layer, located between adjacent two sub-pixels, and at least includes a body structure and a top structure covering the body structure. The display panel further includes a third electrode covering the top structure and in contact with the top structure. The overhang structure is conductive. The second electrodes of adjacent two sub-pixels are in contact with side surfaces of the overhang structure, the second electrode of each sub-pixel is disconnected from the third electrode, and the overhang structure and the third electrode collectively function as an auxiliary cathode.

### CROSS-REFERENCE TO RELATED APPLICATIONS

This application claims priority to Chinese Patent Application No. 202411730518.0, filed on November 28, 2024 in the National Intellectual Property Administration of China, the contents of which are herein incorporated by reference in their entireties.

### TECHNICAL FIELD

Embodiments of the present disclosure relate to the technical field of displays, and in particular to a display panel and a manufacturing method therefor, and a display device.

### BACKGROUND

Organic light-emitting diodes (OLEDs) have advantages such as area lighting, cold light, energy efficiency, fast response, flexibility, ultra-thinness, low cost, etc. In the process of manufacturing OLEDs, maskless (i.e., without using masks) deposition and photo lithography are often used to pattern pixels, where overhang structures replace fine metal masks (FMMs), enabling FMM-free processes, independent pixels, and high precision.

However, in the related art, overhang structures in display panels have low strength, poor toughness, and large widths, which reduce pixel aperture ratios. Additionally, cathodes of pixels of the display panels have high resistance and poor uniformity.

### SUMMARY OF THE DISCLOSURE

Some embodiments of the present disclosure may provide a display panel, a manufacturing method therefor, and a display device.

In one aspect, a display panel is provided. The display panel includes a substrate, a plurality of sub-pixels, a pixel definition layer, and an overhang structure. The plurality of sub-pixels are disposed on a side of the substrate, each of the plurality of sub-pixels includes a first electrode, a light-emitting layer, and a second electrode, and the first electrode, the light-emitting layer, and the second electrode are sequentially stacked on one another. The pixel definition layer is disposed on the side of the substrate and defining positions of the plurality of sub-pixels. The overhang structure is disposed on a side of the pixel definition layer away from the substrate, located between adjacent two of the plurality of sub-pixels, and at least includes a body structure and a top structure disposed on a surface of the body structure away from the substrate and covering the body structure. The display panel further includes a third electrode covering a side of the top structure away from the substrate and in contact with the top structure. The overhang structure is a conductive structure. The second electrodes of adjacent two of the plurality of sub-pixels are in contact with side surfaces of the overhang structure, the second electrode of each of the plurality of sub-pixels is disconnected from the third electrode, and the overhang structure and the third electrode collectively function as an auxiliary cathode.

In another aspect, a method for manufacturing a display panel is further provided. The method includes: providing a substrate and forming first electrodes of a plurality of sub-pixels and a pixel definition layer on a side of the substrate; forming an overhang structure on a side of the pixel definition layer away from the substrate using a 3D printing process, where the overhang structure at least comprises a body structure and a top structure, the top structure is disposed on a surface of the body structure away from the substrate and covers the body structure, and the overhang structure is a conductive structure; sequentially forming light-emitting layers of the plurality of sub-pixels; and depositing an electrode layer to form second electrodes covering the light-emitting layers of the plurality of sub-pixels and a third electrode covering a side of the top structure away from the substrate and in contact with the top structure. The second electrodes are disconnected from the third electrode, and the overhang structure and the third electrode collectively function as an auxiliary cathode.

In an additional aspect, a display device is further provided. The display device includes a display panel and a power supply configured to supply power to the display panel. The display panel may be the one as described above, or a display panel manufactured by using the display panel manufacturing method as described above.

### BRIEF DESCRIPTION OF THE DRAWINGS

To more clearly illustrate the technical solutions in the embodiments of the present disclosure or the related art, the following will briefly introduce the accompanying drawings required for describing the embodiments or the related art. It is evident that the drawings in the following description are merely some embodiments of the present disclosure. For those skilled in the art, other drawings can be derived from these drawings without creative efforts.

FIG. 1 is a schematic structural view of a display panel according to a first embodiment of the present disclosure.

FIG. 2 is a top view illustrating distribution positions of first electrodes, second electrodes, and auxiliary cathode in the display panel of FIG. 1.

FIG. 3 is a schematic structural view of a display panel according to a second embodiment of the present disclosure.

FIG. 4 is a flowchart diagram of a manufacturing method for a display panel according to a third embodiment of the present disclosure.

FIG. 5 is a structural schematic view corresponding to an operation S1 of FIG. 4 in some implementations of the present disclosure.

FIG. 6 is a structural schematic view corresponding to an operation S2 of FIG. 4 in some implementations of the present disclosure.

FIG. 7 is a structural schematic view corresponding to an operation S3 of FIG. 4 in some implementations of the present disclosure.

FIG. 8 is a structural schematic view corresponding to an operation S4 of FIG. 4 in some implementations of the present disclosure.

FIG. 9 is a schematic structural view of a display device according to a fourth embodiment of the present disclosure.

### DETAILED DESCRIPTION

The technical solutions in some embodiments of the present disclosure will be clearly and completely described below with reference to the accompanying drawings. It is evident that the described embodiments are only part of the embodiments of the present disclosure and not all embodiments. Based on the embodiments of the present disclosure, all other embodiments obtained by those skills in the art without any creative effort fall within the scope of the present disclosure.

The terms “first”, “second”, and “third” in some embodiments of the present disclosure are merely used for descriptive purposes and should not be construed as indicating or implying relative importance or implicitly indicating the quantity of the indicated technical features. Thus, the features limited by “first” “second” and “third” may explicitly or implicitly include at least one such feature. Furthermore, the terms “including” and “having” and any variations thereof, are intended to cover non-exclusive inclusion. For example, a process, method, system, product, or device that includes a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification are not necessarily all referring to the same embodiment, nor are they mutually exclusive alternative embodiments. It is explicitly and implicitly understood by those skills in the art that the embodiments described herein may be combined with other embodiments.

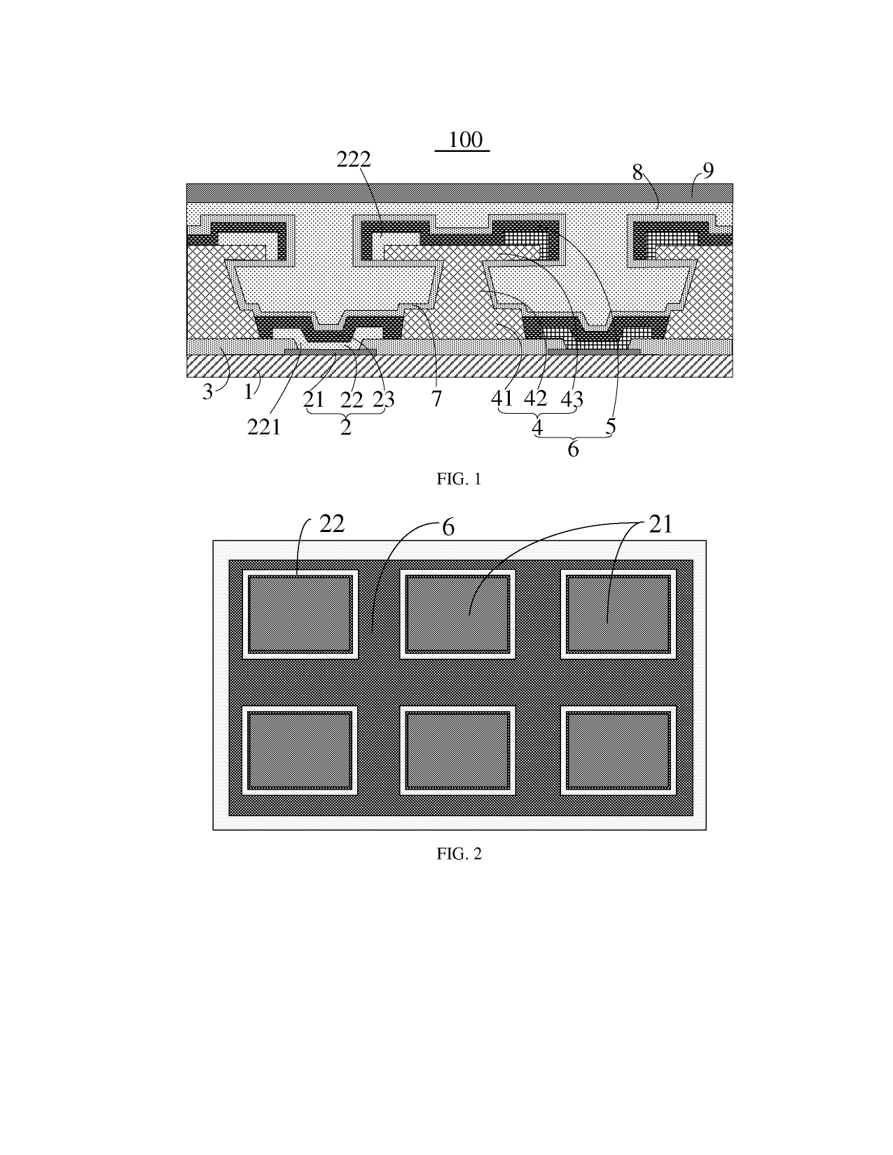

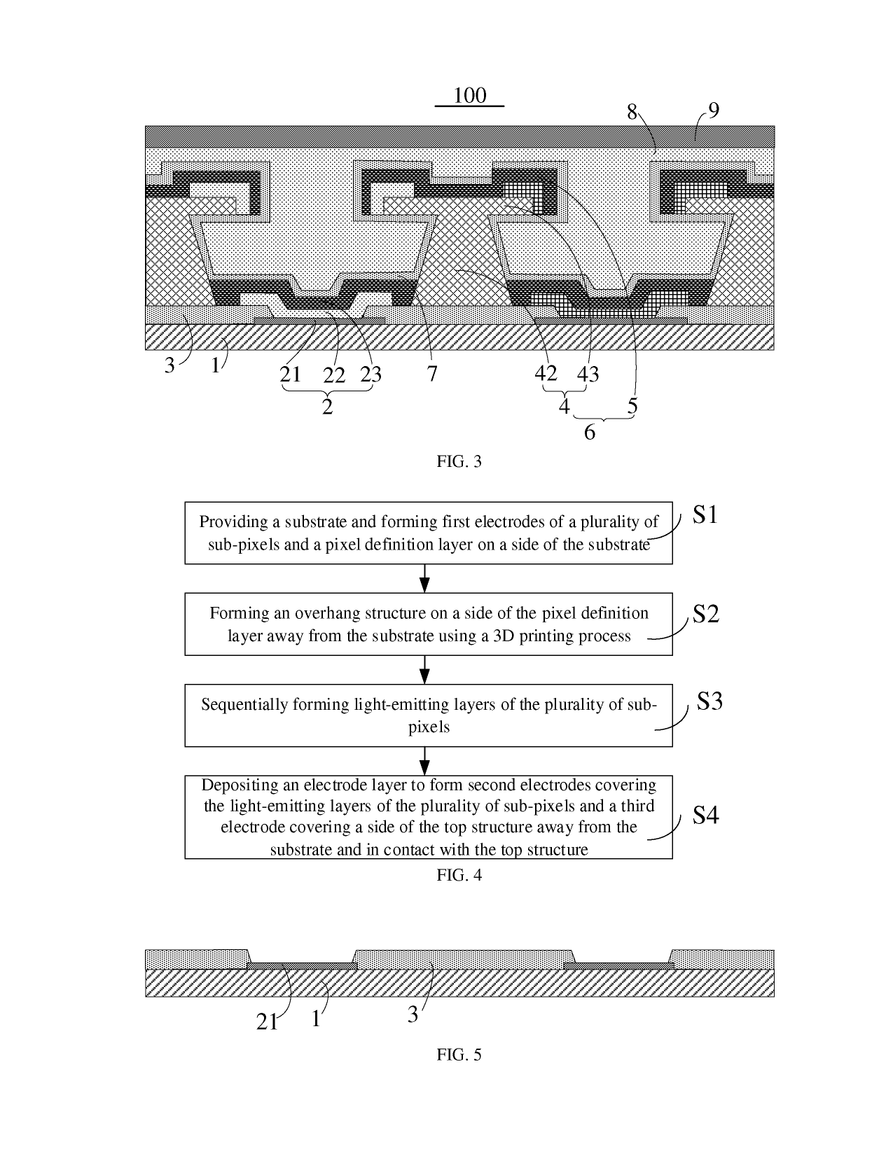

As shown in FIG. 1 to FIG. 3, FIG. 1 is a schematic structural view of a display panel according to a first embodiment of the present disclosure, FIG. 2 is a top view illustrating distribution positions of first electrodes, second electrodes, and auxiliary cathode in the display panel of FIG. 1, and FIG. 3 is a schematic structural view of a display panel according to a second embodiment of the present disclosure.

As shown in FIG. 1 to FIG. 3, some embodiments of the present disclosure provide a display panel 100. The display panel 100 may include a substrate 1, a plurality of sub-pixels 2, a pixel definition layer 3, and an overhang structure 4. In some embodiments, the substrate 1 may be a driving substrate. A drive circuit layer (not shown) is disposed on one side of the substrate 1 and may include a plurality of thin-film transistors (TFTs, not shown). The plurality of sub-pixels 2 are disposed on the substrate 1. In some embodiments, the plurality of sub-pixels 2 may be disposed on a side of the drive circuit layer away from the substrate 1. Each sub-pixel 2 may include a first electrode 21, a light-emitting layer 22, and a second electrode 23. The first electrode 21, the light-emitting layer 22, and the second electrode 23 are sequentially stacked on one another. In some embodiments, the first electrode 21 may serve as the anode of the sub-pixel 2, and the second electrode 23 may serve as the cathode of the sub-pixel 2. The pixel definition layer 3 may be disposed on the same side of the substrate 1 where the plurality of sub-pixels 2 are located and define positions of the plurality of sub-pixels 2. The overhang structure 4 may be disposed on a side of the pixel definition layer 3 away from the substrate 1 and located between adjacent two of the plurality of sub-pixels 2. The overhang structure 4 may include at least a body structure 42 and a top structure 43. The top structure 43 may be disposed on a surface of the body structure 42 away from the substrate 1 and cover or shield the body structure 42. In some embodiments, the overhang structure 4 may be a conductive structure. The second electrodes 23 of adjacent two of the plurality of sub-pixels 2 may be both in contact with side surfaces of the overhang structure 4. The display panel 100 may further include a third electrode 5, and the third electrode 5 covers a side of the top structure 43 away from the substrate 1 and is in contact with the top structure 43. The second electrodes 23 of the plurality sub-pixels 2 may be disconnected from the third electrode 5. The overhang structure 4 and the third electrode 5 may collectively function as an auxiliary cathode 6.

It is understood that, by configuring the entire overhang structure 4 as a conductive structure, the strength of the overhang structure 4 is enhanced, and the width of the overhang structure 4 is reduced, thereby improving the pixel aperture ratio of the display panel 100. Besides, the second electrodes 23 of adjacent two of the plurality of sub-pixels 2 are in contact with the side surfaces of the overhang structure 4, such that the cathodes of the plurality of sub-pixels 2 may be electrically interconnected to each other through the overhang structure 4. In this way, full-surface interconnection among the cathodes of all sub-pixels 2 may be achieved, the resistance of the cathodes may be reduced, and the uniformity of the cathodes of the plurality of sub-pixels 2 may be improved. Furthermore, the display panel 100 includes the third electrode 5, and the third electrode 5 covers the side of the top structure 43 away from the substrate 1 and is in contact with the top structure 43. In this way, the third electrode 5 may be electrically connected to the overhang structure 4, such that the third electrode 5 and the overhang structure 4 may cooperatively function as the auxiliary cathode 6. Thus, the thickness of the auxiliary cathode 6 may be increased, and the auxiliary cathode 6 may have a full-surface mesh-like structure across the entire surface. This design may further reduce the overall resistance (or full-surface resistance) of the cathodes and improve the uniformity of the cathodes across the entire surface. Therefore, the issues of low strength and large width of the overhang structure and high resistance and poor uniformity of the cathodes of the pixels in the related art may be addressed, and the performance and the display quality of the display panel 100 may be improved.

In some embodiments, as shown in FIGS. 1-2, the overhang structure 4 may include a base structure 41, the body structure 42, and the top structure 43. The base structure 41, the body structure 42, and the top structure 43 may be sequentially stacked on one another. The top structure 43 may be disposed on the surface of the body structure 42 away from the substrate 1 and cover the body structure 42. The base structure 41 may be disposed on a side of the body structure 42 adjacent to the pixel definition layer 3. The top structure 43 may have the largest width to shield or cover the body structure 42. That is, a width of the top structure 43 is greater than that of the body structure 42 and further greater than that of the base structure 41. In some embodiments, the overhang structure 4 adopts a three-layer configuration with varying widths, which enhances structural strength and stability of the overhang structure 4. In some implementations, as shown in FIG. 1, a vertical cross-sectional shape of the base structure 41 may be approximately trapezoidal. A vertical cross-sectional shape of the body structure 42 may be regular trapezoidal. A width of a bottom end of the body structure 42 may be smaller than that of the base structure 41. A slope of the side surface of the body structure 42 may be relatively steep. A vertical cross-sectional shape of the top structure 43 may be substantially rectangular. A width of the top structure 43 may be greater than that of the body structure 42 to shield or cover the body structure 42. By utilizing the overhang structure 4, the light-emitting layers 22 and the second electrodes 23 of the sub-pixels 2 may be deposited directly within pixel accommodation areas defined by the pixel definition layer 3 without needing fine metal masks (FMMs). The overhang structure 4 may separate different sub-pixels 2 from each other, such that the sub-pixels 2 may be independent from each other. In some embodiments, the bottom end of the body structure 42 may refer to an end of the body structure 42 adjacent to the substrate 1, a top end of the body structure 42 may refer to an end of the body structure 42 away from the substrate 1, and the side surface of the body structure 42 may refer to the surface connecting the top end of the body structure 42 and the bottom end of the body structure 42.

The overhang structure 4 may be an integrated structure or a one-piece structure, i.e., the base structure 41, body structure 42, and top structure 43 may be integrally formed together. In some embodiments, the overhang structure 4 may be formed in a single molding operation via a 3D printing process. That is, materials are directly deposited by using 3D printing technology to directly create the integrated overhang structure 4 including the base structure 41, the body structure 42, and the top structure 43 in a single molding operation.

In the overhang structure 4, the body structure 42, the top structure 43, and the base structure 41 are all conductive structures. The material of the overhang structure 4 may include a metal, a metal oxide, or a multi-metal alloy, either individually or in combination. For example, the material of the overhang structure 4 may be an elemental metal such as aluminum (Al), copper (Cu), molybdenum (Mo), nickel (Ni), titanium (Ti), magnesium (Mg), silver (Ag), calcium (Ca), lithium (Li), etc. Alternatively, the material of the overhang structure 4 may be a conductive metal oxide such as indium tin oxide (ITO), indium zinc oxide (IZO), etc. The material of the overhang structure 4 may also be a multi-metal alloy including two or more metallic materials. In some embodiments, the material of the overhang structure 4 may be a low-resistivity conductive metal, metal oxide, or multi-metal alloy. The material of the overhang structure 4 may be selected based on application requirements, provided that the material has conductivity to ensure the manufactured overhang structure 4 is conductive. The present disclosure imposes no limitations on the material choice.

It is understood that, the overhang structure 4, manufactured directly via 3D printing technology using the material such as the metal, the metal oxide, or the multi-metal alloy, allows the base structure 41, the body structure 42, and the top structure 43 (originally designed as a three-layer configuration) to be directly formed in a single molding operation. In this way, there is no need for layer-by-layer deposition and etching processes to individually form the base structure 41, the body structure 42, and the top structure 43. Consequently, the manufacturing processes may be simplified, and production operations may be reduced. Besides, the overhang structure 4 may be produced as an integrated or one-piece structure, which enhances the strength of the overhang structure 4.

Compared to related art where the body structure and the top structure are manufactured using inorganic insulating materials, the base structure 41, the body structure 42, and the top structure 43 of the overhang structure 4 in some embodiments of the present disclosure are formed from materials such as metals, metal oxides, multi-metal alloys, etc. Thus, the base structure 41, the body structure 42, and the top structure 43 may have higher structural strength, and the issues such as layer delamination or collapse during subsequent stacking of an encapsulation layer caused by the low strength, poor toughness, and brittle film properties of the inorganic insulating materials in related art may be addressed. Additionally, the overhang structure 4 may have a large or enhanced strength, and thus there is no need for a large width which is required when forming the overhang structure 4 by using the inorganic insulating materials. This allows the width of the overhang structure 4 to be reduced. Besides, the slope or gradient of the body structure 42 is steeper, which increases the pixel aperture ratio of the display panel 100 and reduces the impact of the overhang structure 4 on the pixel aperture ratio. Consequently, the display performance may be improved, making the design more suitable for high-PPI (Pixels Per Inch) products. Furthermore, the overhang structure 4, manufactured from materials such as metals, metal oxides, multi-metal alloys, etc., may have better structural stability under bending deformation, which may extend the operational lifespan of the product.

In the related art, in a case where a film is formed from metals or multi-metal alloys by using methods such as sputtering etc., the thickness of the formed film may be difficult to achieve a micrometer-level dimension. Due to the thinness of the films, if the body structure 42 is manufactured directly by sputtering metals or multi-metal alloys, a first portion 221 of the light-emitting layer 22 in the pixel accommodation area defined by the pixel definition layer 3 may fail to disconnect from a second portion 222 of the light-emitting layer 22 deposited above the top structure 43 of the overhang structure 4, which may affect the normal performance of the display panel 100. Consequently, in the related art, it is hard to utilize materials such as metals or multi-metal alloys to manufacture the body structure of the overhang structure. In some embodiments of the present disclosure, the overhang structure 4 may be directly manufactured using the 3D printing technology with the materials such as metals, metal oxides, multi-metal alloys, etc. This approach reduces the limitations in the related art in utilizing materials such as metals or multi-metal alloys to manufacture the body structure of the overhang structure, enabling the overhang structure 4 to achieve higher strength and smaller width.

The overhang structure 4, formed by using the 3D printing technology with the materials such as metals, metal oxides, or multi-metal alloys, achieves a nanoscale width. In some embodiments, the top structure 43 may have a width ranging from 200 nm to 1000 nm. By setting the width of the top structure 43 within this range, the overall width of the overhang structure 4 may be reduced, the impact of the overhang structure 4 on the pixel aperture may be significantly reduced, and the pixel aperture ratio of the display panel 100 may be further improved. Additionally, the body structure 42 has a steeper slop, and the steeper slope of the body structure 42 facilitates separating adjacent sub-pixels 2 from each other, and the performance of the display panel 100 may be improved.

In other embodiments, the overhang structure 4, which includes the base structure 41, the body structure 42, and the top structure 43 and which is manufactured by using materials such as metals, metal oxides, or multi-metal alloys, may also be manufactured by using alternative manufacturing processes. These processes may be selected as needed based on application requirements.

As shown in FIG. 1, in some embodiments, the second electrodes 23 of adjacent two of the plurality of sub-pixels 2 are both in contact with the base structure 41. Since the base structure 41 is a conductive structure, the contact between the second electrodes 23 (cathodes) of adjacent two of the plurality of sub-pixels 2 and the base structure 41 enables the cathodes to be electrically connected to each other. Consequently, the cathodes of all sub-pixels 2 in the display panel 100 may achieve full-surface electrical interconnection, forming a mesh-like interconnection network across the cathodes of all sub-pixels 2. This configuration improves the uniformity of the signals in the cathodes of all sub-pixels 2.

In some implementations, the third electrode 5 of the display panel 100 may cover on the side of the top structure 43 away from the substrate 1. The third electrode 5 may be in contact with the top structure 43, and the top structure 43 and the third electrode 5 may cooperatively function as the auxiliary cathode 6. In some implementations, as shown in FIG. 1, the second portion 222 of the light-emitting layer 22 of each sub-pixel 2 may be disposed on the surface of the top structure 43 away from the substrate 1. The second portions 222 of the light-emitting layers 22 of adjacent two of the plurality of sub-pixels 2 disposed on the top structure 43 are spaced apart from each other. That is, the surface of the top structure 43 away from the substrate 1 is not completely covered by the second portion 222 of the light-emitting layer 22 overlying or located above the top structure 43, and a surface of an exposed portion of the top structure 43 away from the substrate 1 may remain exposed by a gap between the second portions 222 of the light-emitting layers 22 of adjacent two of the plurality of sub-pixels 2. The third electrode 5 covers both the second portion 222 of the light-emitting layer 22 on the top structure 43 and the exposed portion of the top structure 43. In some embodiments, the third electrode 5 may completely cover or shield the surface of the second portion 222 of the light-emitting layer 22 on the top structure 43 away from the substrate 1 and the surface of the exposed portion of the top structure 43 exposed from the second portion 222 of the light-emitting layers 22 away from the substrate 1. This configuration ensures the third electrode 5 to be in contact with the top structure 43 of the overhang structure 4.

As the overhang structure 4 is entirely conductive and both the third electrode 5 and the overhang structure 4 are conductive structures, the third electrode 5 disposed on the top of the overhang structure 4 directly contacts the overhang structure 4. This allows the third electrode 5 and the entire overhang structure 4 to collectively function as the auxiliary cathode 6, which increases the thickness of the auxiliary cathode 6. Furthermore, both the overhang structure 4 and the third electrode 5 on the top of the overhang structure 4 are full-surface mesh-shaped structures (as shown in FIG. 2), such that the auxiliary cathode 6 has a full-surface mesh-shaped structure. Herein, the overhang structure 4 and the third electrode 5 being full-surface mesh-shaped structures means that all overhang structures 4 of the display panel 100 are interconnected to each other to form a mesh-shape structure, and all third electrodes 5 of the display panel 100 are interconnected to each other to form a mesh-shape structure. Similarly, the auxiliary cathode 6 having a full-surface mesh-shaped structure means that all auxiliary cathodes 6 of the display panel 100 are interconnected to each other to form a mesh-shape structure. In some embodiments, as shown in FIG. 2, the first electrodes 21 (anodes) of the sub-pixels 2 in a display area of the display panel 100 are discrete or separated planar electrodes. Gap regions (i.e., spaces between the anodes of adjacent two of the plurality of sub-pixels 2) provide large area for the auxiliary cathode 6, and the gap regions may be interconnected to each other to form an interconnected mesh-like structure, which facilitates reducing resistance. Moreover, the auxiliary cathode 6 is electrically connected to the cathode of the corresponding sub-pixel 2. This configuration may further reduce the overall resistance of the cathodes of all sub-pixels 2 of the display panel 100 and improve the uniformity of the cathodes of all sub-pixels 2 across the entire surface. The issues of low strength and large width of the overhang structure and high resistance and poor uniformity of the cathodes of the pixels in the related art may be addressed, and the performance and the display quality of the display panel 100 may be improved.

In some embodiments, for the display panel 100, the third electrode 5 and the second electrodes 23 of the plurality of sub-pixels 2 are formed in a single full-surface film-forming process.

It should be noted that the term “single full-surface film-forming process” here means that the third electrode 5 and the second electrodes 23 of all sub-pixels 2 are manufactured through a single film-forming operation. In some embodiments, the third electrode 5 and the second electrodes 23 of all sub-pixels 2 are formed simultaneously, and the third electrode 5 completely covers the top structure 43 of the overhang structure 4. In this way, the manufacturing processes may be simplified, production operations may be reduced, and costs may be lowered.

In some embodiments, after sequentially manufacturing the first electrodes 21 (anodes) of the sub-pixels 2 and the pixel definition layer 3 on the substrate 1, the overhang structure 4 may be manufactured by using the 3D printing technology. The overhang structure 4 may be then directly utilized as a barrier structure to block the material of the light-emitting layer 22, and the light-emitting layer 22 of the sub-pixel 2 may be deposited within the pixel accommodation area defined by the pixel definition layer 3. The material of the light-emitting layer 22 may be an organic light-emitting material, and the light-emitting layers 22 of different sub-pixels 2 may have different colors. For example, the sub-pixels 2 may include the sub-pixels 22 with three different colors. The light-emitting layers 22 of the sub-pixels 2 may be in red, green, and blue. The light-emitting layers 22 in red, green, and blue may be prepared sequentially. After separately or individually preparing the light-emitting layers 22 in red, green, and blue, an electrode layer may be deposited simultaneously on the light-emitting layers 22 in red, green, and blue, such that the second electrodes 23 are directly formed on the top of the first portion 221 of the light-emitting layers 22 of the sub-pixels 2 within the pixel accommodation areas, and the third electrode 5 covering the side of the top structure 43 of the overhang structure 4 away from the substrate 1 and in contact with the top structure 43 may be formed on the top of the overhang structure 4. By manufacturing the cathodes (second electrodes 23) of the sub-pixels 2 and the third electrode 5 simultaneously, the manufacturing operations of the films may be reduced.

In some embodiments, as shown in FIG. 1, the display panel 100 may further include a protection layer 7, an organic encapsulation layer 8, and an inorganic encapsulation layer 9. The protection layer 7, the organic encapsulation layer 8, and the inorganic encapsulation layer 9 may be stacked sequentially on a side of the third electrode 5 away from the substrate 1.

A material of the protection layer 7 may be an inorganic insulating material. In some embodiments, the material of the protection layer 7 may be a silicon nitride-based inorganic material.

The protection layer 7 may completely cover the second electrodes 23 of all sub-pixels 2, the third electrode 5, and the side surfaces of the overhang structure 4 across the entire surface. In other words, the protection layer 7 may be configured to encapsulate or wrap all structures located between the bottom of the protection layer 7 and the substrate 1, in order to protect the organic light-emitting layers 22 and the second electrodes 23 of the sub-pixels 2, and protect the third electrode 5 on the top of the overhang structure 4. In some embodiments, since the overhang structure 4 includes three layers including the base structure 41, the body structure 42, and the top structure 43, the protection layer 7 may have a gentler slope at the junction between a portion of the protection layer 7 covering the second electrode 23 of the sub-pixel 2 and another portion of the protection layer 7 covering the corresponding side surface of the overhang structure 4. Thus, the protection layer 7 may be less prone to cracking or delamination and may have a high structural strength, which may improve the protection to the display panel 100.

The organic encapsulation layer 8 may be made of an organic material. The organic encapsulation layer 8 may cover a side of the protection layer 7 away from the substrate 1. In some embodiments, a surface of the organic encapsulation layer 8 away from the substrate 1 may be planar. The inorganic encapsulation layer 9 may include an inorganic insulating material and may cover a side of the organic encapsulation layer 8 away from the substrate 1.

By adopting an encapsulation structure including the inorganic protection layer 7, the organic encapsulation layer 8, and the inorganic encapsulation layer 9, the display panel 100 combines the advantages of good moisture/oxygen barrier properties from inorganic materials and excellent film-forming properties from organic materials. This structure isolates the display panel 100 from the external environment, reducing the occurrence of contamination or corrosion caused by airborne impurities, oxygen, moisture, and other contaminants while also resisting mechanical damage when suffering from an external force. Consequently, the encapsulation reliability may be improved, the operational lifespan of the device may be extended, and the stability of the device may be improved.

As shown in FIG. 3, in another embodiment, differing from the display panel 100 described in the first embodiment, the overhang structure 4 in this embodiment may include only the body structure 42 and the top structure 43 stacked on one another, but does not include the base structure 41 positioned between the body structure 42 and the pixel definition layer 3. In some embodiments, the overhang structure 4 including the body structure 42 and top structure 43 is manufactured directly in a single stacking operation by using the 3D printing technology. The overhang structure 4 is also an integrated or one-piece structure and is formed by using the 3D printing technology in a single-operation molding.

In some embodiments, the body structure 42 may have a vertical cross-sectional shape of an isosceles trapezoid, while the top structure 43 may have a vertical cross-sectional shape of a rectangle. The width of the top structure 43 may be greater than that of the body structure 42 to completely cover or shield the body structure 42. The second electrodes 23 (i.e., cathodes) of adjacent two of the plurality of sub-pixels 2 are directly in contact with the side surfaces of the body structure 42, whereas the light-emitting layers 22 of the sub-pixels 2 do not contact the body structure 42. In this way, the cathodes of adjacent two of the plurality sub-pixels 2 may be electrically connected to each other directly via the body structure 42, thereby achieving full-surface interconnection among the cathodes of all sub-pixels 2; i.e., all sub-pixels 2 are interconnected to each other. As a result, the overall resistance of the cathodes of all sub-pixels 2 may be reduced, and the uniformity of the cathodes of the pixels may be improved.

It may be understood that, compared to the three-layer overhang structure 4 in the first embodiment of the display panel 100, the overhang structure 4 in this embodiment may include only the two-layer stacked configuration including the body structure 42 and the top structure 43. The thickness of the overhang structure 4 may be reduced, which enables a thinner design for the display panel 100. Therefore, diverse application requirements may be met, and the potential application scenarios of the display panel 100 may be broadened.

In some embodiments, the remaining structures and configurations of the display panel 100 are consistent with those in the first embodiment and can achieve the same or similar technical effects. Therefore, detailed descriptions for these remaining structures and configurations may refer to the relevant descriptions in the first embodiment, which are not repeated here.

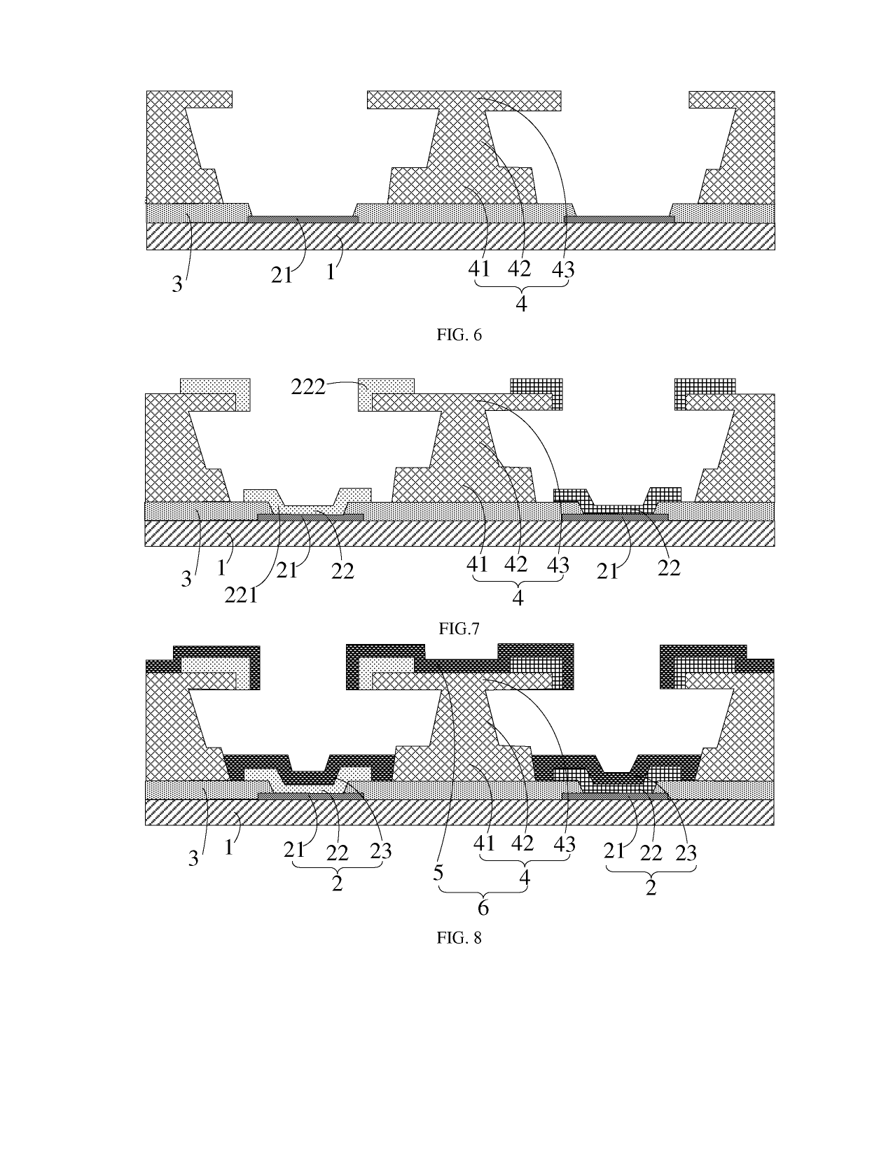

As shown in FIGS. 4-8, FIG. 4 is a flowchart diagram of a manufacturing method for a display panel according to a third embodiment of the present disclosure, FIG. 5 is a structural schematic view corresponding to an operation S1 of FIG. 4 in some implementations of the present disclosure, FIG. 6 is a structural schematic view corresponding to an operation S2 of FIG. 4 in some implementations of the present disclosure, FIG. 7 is a structural schematic view corresponding to an operation S3 of FIG. 4 in some implementations of the present disclosure, and FIG. 8 is a structural schematic view corresponding to an operation S4 of FIG. 4 in some implementations of the present disclosure.

As shown in FIG. 4, some embodiments of the present disclosure may provide a manufacturing method for the display panel 100. The method may be used to manufacture any of the display panels 100 described above. In some embodiments, the manufacturing method may include the following operations.

In an operation S1: a substrate 1 may be provided, and first electrodes 21 of a plurality of sub-pixels 2 and a pixel definition layer 3 may be formed and arranged on one side of the substrate 1.

First, the substrate 1 may be provided. In some embodiments, the substrate 1 may be a driving substrate. A drive circuit layer is disposed on a side of the substrate 1 and may include a plurality of TFTs. Subsequently, the first electrodes 21 of the plurality of sub-pixels 2 and the pixel definition layer 3 may be formed on a side of the substrate 1. In some embodiments, an electrode layer may be first deposited on a side of the drive circuit layer away from the substrate 1. The electrode layer may be a first electrode layer and covers a surface of the substrate 1. The first electrode layer may be processed by using a patterning process to form a plurality of first electrodes 21 spaced apart from each other, and the first electrodes 21 may serve as the anodes of the sub-pixels 2. An insulating film layer may be deposited on a side of the plurality of first electrodes 21 away from the substrate 1. The insulating film layer may completely cover the side of the first electrodes 21 of all the sub-pixels 2 away from the substrate 1 across the entire surface and cover the surface of a portion of the substrate 1,which is exposed from the plurality of first electrodes 21, at a side adjacent to the plurality of first electrodes 21. The insulating film layer may be further patterned to form the pixel definition layer 3. The pixel definition layer 3 may define a plurality of pixel accommodation areas and expose the plurality of first electrodes 21.

In some implementations, the structure shown in FIG. 5 may be obtained after completing the operation S1.

In an operation S2: an overhang structure 4 may be formed on a side of the pixel definition layer 3 away from the substrate 1 by using a 3D printing process.

In some embodiments, the overhang structure 4 may be manufactured on the side of the pixel definition layer 3 away from the substrate 1 by using the 3D printing process. The overhang structure 4 may include at least a body structure 42 and a top structure 43. The top structure 43 may be positioned on a surface of the body structure 42 away from the substrate 1 and cover or shield the body structure 42. The overhang structure 4 may be a conductive structure.

In some implementations, the overhang structure 4 may include only the body structure 42 and the top structure 43, where both the body structure 42 and the top structure 43 are conductive structures. In some implementations, the overhang structure 4 may include the base structure 41, the body structure 42, and the top structure 43. The base structure 41 may be disposed on a side of the body structure 42 adjacent to the pixel definition layer 3, and the base structure 41, the body structure 42, and the top structure 43 are all conductive structures.

The material of the overhang structure 4 may include a metal, a metal oxide, or a multi-metal alloy, either individually or in combination. For example, the material of the overhang structure 4 may be an elemental metal such as aluminum (Al), copper (Cu), molybdenum (Mo), nickel (Ni), titanium (Ti), magnesium (Mg), silver (Ag), calcium (Ca), lithium (Li), etc. Alternatively, the material of the overhang structure 4 may be a conductive metal oxide such as indium tin oxide (ITO), indium zinc oxide (IZO), etc. The material of the overhang structure 4 may also be a multi-metal alloy including two or more metallic materials. In some embodiments, the material of the overhang structure 4 may be a low-resistivity conductive metal, metal oxide, or multi-metal alloy.

In some embodiments, the overhang structure 4 having a one-piece structure or an integrated structure may be formed by directly stacking the aforementioned materials in a single operation by using the 3D printing process. In other words, the overhang structure 4 may be formed by using the 3D printing process in a single-operation molding, which reduces manufacturing operations and saves costs. This approach reduces the limitations in the related art in utilizing materials such as metals or multi-metal alloys to manufacture the body structure of the overhang structure. Additionally, the overhang structure 4 formed by the 3D printing process with these materials may have higher structural strength and better structural stability under bending deformation, which may extend the operational lifespan of the product. The width of the overhang structure 4 may be reduced. In some embodiments, width of the overhang structure 4 may be reduced to the nanoscale. In some implementations, the top structure 43 may have a width ranging from 200 nm to 1000 nm, which facilitates improving the pixel aperture ratio of the display panel 100 and makes it more suitable for high-PPI (Pixels Per Inch) products. The slope or gradient of the body structure 42 is steeper, which facilitates separating adjacent sub-pixels 2 from each other, and the performance of the display panel 100 may be improved.

In some implementations, the structure shown in FIG. 6 may be obtained after completing the operation S2. In other implementations, the manufactured overhang structure 4 may also adopt a two-layer structure including only the body structure 42 and the top structure 43.

In an operation S3: light-emitting layers 22 of the plurality of sub-pixels 2 may be manufactured or prepared sequentially.

In some embodiments, first portions 221 of the light-emitting layers 22 of the sub-pixels 2 may be deposited within the pixel accommodation areas defined by the pixel definition layer 3. The first portions 221 of the light-emitting layers 22 may cover the surfaces of the first electrodes 21 away from the substrate 1 and partially extend onto the surface of the pixel definition layer 3 away from the substrate 1. The first portions 221 of the light-emitting layers 22 are spaced apart from the side surfaces of the overhang structure 4, i.e., the first portions 221 of the light-emitting layers 22 in the pixel accommodation areas does not contact with the side surfaces of the base structure 41 or the body structure 42 of the overhang structure 4. The material of each of the light-emitting layers 22 may be an organic light-emitting material.

The light-emitting layers 22 of different sub-pixels 2 may have different colors. For example, the sub-pixels 2 may include the sub-pixels 22 with three different colors. The light-emitting layers 22 of the sub-pixels 2 may be in red, green, and blue. The light-emitting layers 22 in red, green, and blue may be prepared sequentially.

In some implementations, a second portion 222 of the light-emitting layer 22 of each sub-pixel 2 may be deposited on the surface of the top structure 43 of the overhang structure 4 away from the substrate 1. The second portions 222 of the light-emitting layers 22 of adjacent two of the plurality of sub-pixels 2 located on the top structure 43 are spaced apart from each other. That is, the surface of the top structure 43 away from the substrate 1 is not completely covered by the second portion 222 of the light-emitting layer 22 overlying or located above the top structure 43, and a surface of an exposed portion of the top structure 43 away from the substrate 1 may remain exposed by a gap between the second portions 222 of the light-emitting layers 22 of adjacent two of the plurality of sub-pixels 2.

In some implementations, the structure shown in FIG. 7 may be obtained after completing the operation S3.

In an operation S4: an electrode layer may be deposited to form second electrodes 23 covering the first portions 221 of the light-emitting layers 22 of the plurality of sub-pixels 2 and a third electrode 5 covering a side of the top structure 43 away from the substrate 1 and in contact with the top structure 43.

In some embodiments, an electrode layer (referred to as the second electrode layer) may be deposited on the side of the light-emitting layers 22 away from the substrate 1, such that the second electrodes 23 covering the first portions 221 of the light-emitting layers 22 of the plurality of sub-pixels 2 and the third electrode 5 covering the side of the top structure 43 away from the substrate 1 and in contact with the top structure 43 may be formed. The third electrode 5 may be separated or disconnected from the second electrodes 23 of the sub-pixels 2.

In some embodiments, the second electrodes 23 may serve as the cathodes of the sub-pixels 2. The side surfaces of the second electrodes 23 of adjacent two sub-pixels 2 are in contact with the side surfaces of the overhang structure 4. In some implementations, the overhang structure 4 may include the base structure 41, the body structure 42, and the top structure 43. The side surfaces of the second electrodes 23 of adjacent two sub-pixels 2 are in contact with the side surfaces of the base structure 41. Since the overhang structure 4 is a conductive structure and the second electrodes 23 of adjacent two sub-pixels 2 are in contact with the side surfaces of the overhang structure 4, the cathodes of adjacent sub-pixels 2 may be electrically connected to each other through the overhang structure 4. In this way, the cathodes of all sub-pixels 2 may be interconnected to each other to form a full-surface cathode, which may reduce the overall resistance of the cathodes of all sub-pixels 2 and improve the uniformity of signals of the cathodes of all sub-pixels 2 throughout the display panel.

The third electrode 5 of the display panel 100 may cover on the side of the top structure 43 away from the substrate 1. The third electrode 5 may be in contact with the top structure 43, and the top structure 43 and the third electrode 5 may cooperatively function as the auxiliary cathode 6. In some implementations, as shown in FIG. 1, the second portion 222 of the light-emitting layer 22 of each sub-pixel 2 may be disposed on the surface of the top structure 43 away from the substrate 1. The second portions 222 of the light-emitting layers 22 of adjacent two of the plurality of sub-pixels 2 disposed on the top structure 43 are spaced apart from each other. The third electrode 5 covers both the second portion 222 of the light-emitting layer 22 on the top structure 43 and the exposed portion of the top structure 43. In some embodiments, the third electrode 5 may completely cover or shield the surface of the second portion 222 of the light-emitting layer 22 on the top structure 43 away from the substrate 1 and the surface of the exposed portion of the top structure 43 exposed from the second portion 222 of the light-emitting layers 22 away from the substrate 1. This configuration ensures the third electrode 5 to be in contact with the top structure 43 of the overhang structure 4.

As the overhang structure 4 is entirely conductive and both the third electrode 5 and the overhang structure 4 are conductive structures, the third electrode 5 disposed on the top of the overhang structure 4 directly contacts the overhang structure 4. This allows the third electrode 5 and the entire overhang structure 4 to collectively function as the auxiliary cathode 6, which increases the thickness of the auxiliary cathode 6. Furthermore, both the overhang structure 4 and the third electrode 5 on the top of the overhang structure 4 are full-surface mesh-shaped structures (as shown in FIG. 2), such that the auxiliary cathode 6 has a full-surface mesh-shaped structure. In some embodiments, the anodes in the display area of the display panel 100 are separated planar electrodes. Gap regions (i.e., spaces between the anodes of adjacent two of the plurality of sub-pixels 2) provide large area for the auxiliary cathode 6, and the gap regions may be interconnected to each other to form an interconnected mesh-like structure, which facilitates reducing resistance. Moreover, the auxiliary cathode 6 is electrically connected to the cathode of the corresponding sub-pixel 2. This configuration may further reduce the overall resistance of the cathodes of all sub-pixels 2 of the display panel 100 and improve the uniformity of the cathodes of all sub-pixels 2 across the entire surface. The issues of low strength and large width of the overhang structure and high resistance and poor uniformity of the cathodes of the pixels in the related art may be addressed, and the performance and the display quality of the display panel 100 may be improved.

The third electrode 5 and the second electrodes 23 of the plurality of sub-pixels 2 are formed in a single full-surface film-forming process; i.e., the third electrode 5 and the second electrodes 23 of the plurality of sub-pixels 2 are manufactured simultaneously from the same electrode layer (i.e., the second electrode layer) with only one deposition operation (i.e., the deposition operation of the electrode layer is performed only once to prepare both the third electrode 5 and the second electrodes 23). Through the single film-forming process, the third electrode 5 completely covering the top structure 43 of the overhang structure 4 and the second electrodes 23 covering the light-emitting layers 22 of the sub-pixels 2 may be formed simultaneously, and the second electrodes 23 are disconnected from the third electrode 5. In this way, the manufacturing processes may be simplified, the production operations may be reduced, and the costs may be lowered.

In some implementations, the structure shown in FIG. 8 may be obtained after completing the operation S4.

Further, after forming the third electrode 5 and the second electrodes 23 of the plurality of sub-pixels 2, the manufactured structure may be further encapsulated. In some embodiments, a protection layer 7, an organic encapsulation layer 8, and an inorganic encapsulation layer 9 may be sequentially deposited on a side of the third electrode 5 away from the substrate 1 to encapsulate the manufactured structure.

A material of the protection layer 7 may be an inorganic insulating material. In some embodiments, the material of the protection layer 7 may be a silicon nitride-based inorganic material. The protection layer 7 may completely cover the second electrodes 23 of all sub-pixels 2, the third electrode 5, and the side surfaces of the overhang structure 4 across the entire surface. In other words, the protection layer 7 may be configured to encapsulate or wrap all structures located between the bottom of the protection layer 7 and the substrate 1, in order to protect the organic light-emitting layers 22 and the second electrodes 23 of the sub-pixels 2, and protect the third electrode 5 on the top of the overhang structure 4. The organic encapsulation layer 8 may be made of an organic material. The organic encapsulation layer 8 may cover a side of the protection layer 7 away from the substrate 1. In some embodiments, a surface of the organic encapsulation layer 8 away from the substrate 1 may be planar. The inorganic encapsulation layer 9 may include an inorganic insulating material and may cover a side of the organic encapsulation layer 8 away from the substrate 1.

By adopting an encapsulation structure including the inorganic protection layer 7, the organic encapsulation layer 8, and the inorganic encapsulation layer 9, the display panel 100 combines the advantages of good moisture/oxygen barrier properties from inorganic materials and excellent film-forming properties from organic materials. This structure isolates the display panel 100 from the external environment, reducing the occurrence of contamination or corrosion caused by airborne impurities, oxygen, moisture, and other contaminants while also resisting mechanical damage when suffering from an external force. Consequently, the encapsulation reliability may be improved, the operational lifespan of the device may be extended, and the stability of the device may be improved.

In some implementations, after depositing the protection layer 7, the organic encapsulation layer 8, and the inorganic encapsulation layer 9 to encapsulate the manufactured structure, the structure of the display panel 100 as shown in FIG. 1 may be obtained.

In other implementations, the overhang structure 4 formed in the operation S2 may include only the body structure 42 and the top structure 43 (a two-layer configuration). After subsequent operations and after performing encapsulation on the manufactured structure, the structure of the display panel 100 as shown in FIG. 3 may also be obtained.

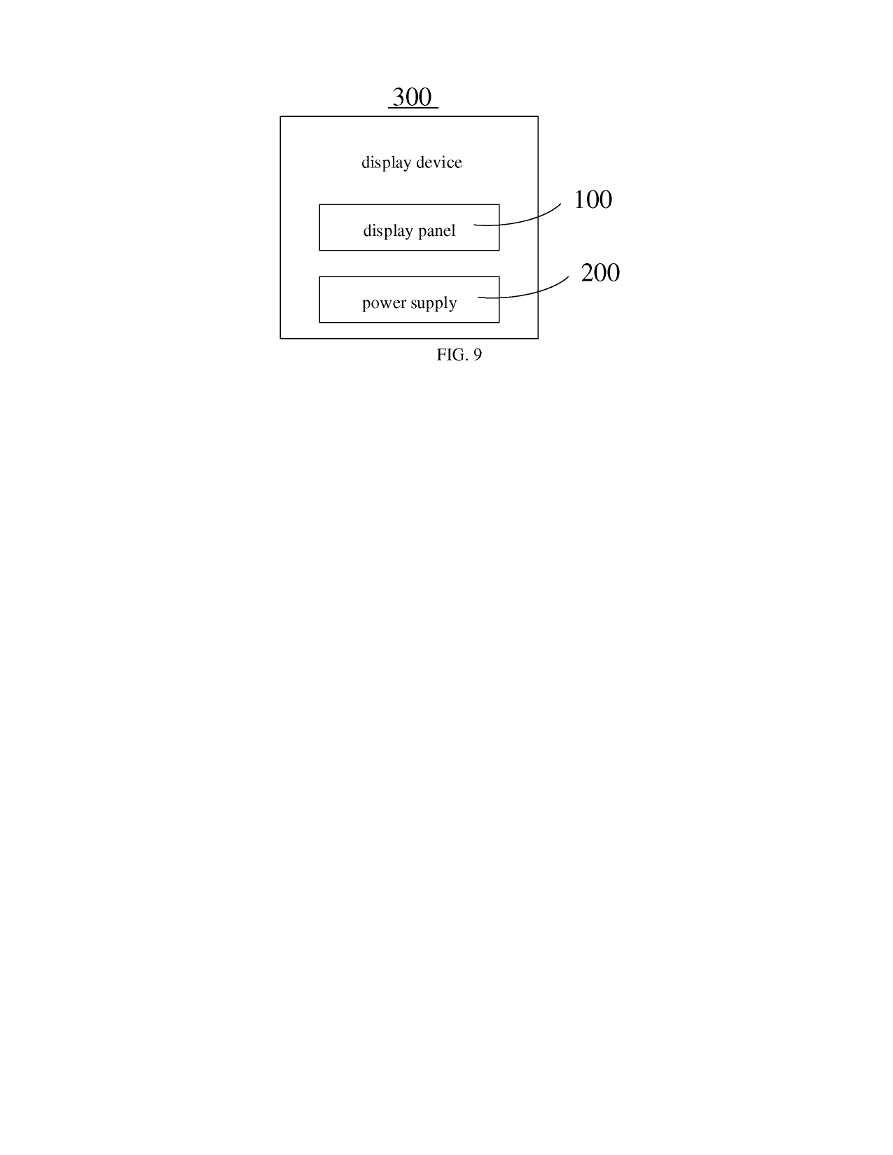

As shown in FIG. 9, FIG. 9 is a schematic structural view of a display device according to a fourth embodiment of the present disclosure.

As shown in FIG. 9, some embodiments of the present disclosure may further provide a display device 300. The display device 300 may include a display panel 100 and a power supply 200. The display panel 100 may be any display panel 100 as described in the first or second embodiment, or a display panel 100 manufactured by using the aforementioned manufacturing method. The power supply 200 may be configured to power the display panel 100, such that the display panel 100 may stably display images and pictures.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A display panel, comprising:
a substrate;
a plurality of sub-pixels, disposed on a side of the substrate, each of the plurality of sub-pixels comprising a first electrode, a light-emitting layer, and a second electrode, and the first electrode, the light-emitting layer, and the second electrode being sequentially stacked on one another;
a pixel definition layer, disposed on the side of the substrate and defining positions of the plurality of sub-pixels; and
an overhang structure, disposed on a side of the pixel definition layer away from the substrate, located between adjacent two of the plurality of sub-pixels, being a conductive structure, and at least comprising:
a body structure; and
a top structure, disposed on a surface of the body structure away from the substrate and covering the body structure; and
a third electrode, covering a side of the top structure away from the substrate and in contact with the top structure;
wherein the second electrodes of adjacent two of the plurality of sub-pixels are in contact with side surfaces of the overhang structure, the second electrode of each of the plurality of sub-pixels is disconnected from the third electrode, and the overhang structure and the third electrode collectively function as an auxiliary cathode.

2. The display panel as claimed in claim 1, wherein a width of a surface of the body structure away from the substrate is smaller than a width of a surface of the top structure adjacent to the substrate.

3. The display panel as claimed in claim 1, wherein the overhang structure is a 3D-printed integrated structure.

4. The display panel as claimed in claim 1, wherein the overhang structure further comprises a base structure disposed on a side of the body structure adjacent to the pixel definition layer; the body structure, the top structure, and the base structure are all conductive structures; and
wherein the second electrodes of adjacent two of the plurality of sub-pixels are both in contact with the base structure.

5. The display panel as claimed in claim 4, wherein a portion of the light-emitting layer of each of the plurality of sub-pixels is disposed on a surface of the top structure away from the substrate, the portions of the light-emitting layers of adjacent two of the plurality of sub-pixels disposed on the top structure are spaced apart from each other; and
wherein the third electrode covers both the portion of the light-emitting layer on the top structure and the top structure.

6. The display panel as claimed in claim 4, wherein a width of a surface of the body structure adjacent to the substrate is smaller than a width of a surface of the base structure away from the substrate.

7. The display panel as claimed in claim 3, wherein an material of the overhang structure comprises at least one selected from the group consisting of a metal, a metal oxide, and a multi-metal alloy.

8. The display panel as claimed in claim 3, wherein the top structure has a width ranging from 200 nm to 1000 nm.

9. The display panel as claimed in claim 1, wherein the third electrode and the second electrodes of the plurality of sub-pixels are simultaneously formed on the light-emitting layers of the plurality of sub-pixels.

10. The display panel as claimed in claim 9, wherein the display panel further comprises:
a protection layer, completely covering the second electrodes of the plurality of sub-pixels, the third electrode, and the side surfaces of the overhang structure;
an organic encapsulation layer, disposed on a side of the protection layer away from the substrate; and
an inorganic encapsulation layer, disposed on a side of the organic encapsulation layer away from the substrate.

11. The display panel as claimed in claim 1, wherein the second electrodes of all of the plurality of sub-pixels are interconnected to each other via the overhang structure; and
wherein the overhang structure and the third electrode are mesh-like structure.

12. A method for manufacturing a display panel, comprising:
providing a substrate and forming first electrodes of a plurality of sub-pixels and a pixel definition layer on a side of the substrate;
forming an overhang structure on a side of the pixel definition layer away from the substrate using a 3D printing process, wherein the overhang structure at least comprises a body structure and a top structure, the top structure is disposed on a surface of the body structure away from the substrate and covers the body structure, and the overhang structure is a conductive structure;
sequentially forming light-emitting layers of the plurality of sub-pixels; and
depositing an electrode layer to form second electrodes covering the light-emitting layers of the plurality of sub-pixels and a third electrode covering a side of the top structure away from the substrate and in contact with the top structure; wherein the second electrodes are disconnected from the third electrode, and the overhang structure and the third electrode collectively function as an auxiliary cathode.

13. The method as claimed in claim 12, wherein the overhang structure is formed in a single operation by using a 3D printing process, and the third electrode and the second electrodes of the plurality of sub-pixels are formed in a single full-surface film-forming process.

14. A display device, comprising:
a display panel, comprising:
a substrate;
a plurality of sub-pixels, disposed on a side of the substrate, each of the plurality of sub-pixels comprising a first electrode, a light-emitting layer, and a second electrode, and the first electrode, the light-emitting layer, and the second electrode being sequentially stacked on one another;
a pixel definition layer, disposed on the side of the substrate and defining positions of the plurality of sub-pixels; and
an overhang structure, disposed on a side of the pixel definition layer away from the substrate, located between adjacent two of the plurality of sub-pixels, being a conductive structure, and at least comprising:
a body structure; and
a top structure, disposed on a surface of the body structure away from the substrate and covering the body structure; and
a third electrode, covering a side of the top structure away from the substrate and in contact with the top structure;
wherein the second electrodes of adjacent two of the plurality of sub-pixels are in contact with side surfaces of the overhang structure, the second electrode of each of the plurality of sub-pixels is disconnected from the third electrode, and the overhang structure and the third electrode collectively function as an auxiliary cathode; and
a power supply, configured to power the display panel.

15. The display device as claimed in claim 14, wherein a width of a surface of the body structure away from the substrate is smaller than a width of a surface of the top structure adjacent to the substrate.

16. The display device as claimed in claim 14, wherein the overhang structure further comprises a base structure disposed on a side of the body structure adjacent to the pixel definition layer; the body structure, the top structure, and the base structure are all conductive structures; and
wherein the second electrodes of adjacent two of the plurality of sub-pixels are both in contact with the base structure.

17. The display device as claimed in claim 16, wherein a portion of the light-emitting layer of each of the plurality of sub-pixels is disposed on a surface of the top structure away from the substrate, the portions of the light-emitting layers of adjacent two of the plurality of sub-pixels disposed on the top structure are spaced apart from each other; and
wherein the third electrode covers both the portion of the light-emitting layer on the top structure and the top structure.

18. The display device as claimed in claim 14, wherein an material of the overhang structure comprises at least one selected from the group consisting of a metal, a metal oxide, and a multi-metal alloy.

19. The display device as claimed in claim 14, wherein the display panel further comprises:
a protection layer, completely covering the second electrodes of the plurality of sub-pixels, the third electrode, and the side surfaces of the overhang structure;
an organic encapsulation layer, disposed on a side of the protection layer away from the substrate; and
an inorganic encapsulation layer, disposed on a side of the organic encapsulation layer away from the substrate.

20. The display device as claimed in claim 14, wherein the second electrodes of all of the plurality of sub-pixels are interconnected to each other via the overhang structure; and
wherein the overhang structure and the third electrode are mesh-like structure.
